(19) United States
(12) Patent Application Publication
(10) Pub. No.: US 2023/0303925 A1
(43) Pub. Date: Sep. 28, 2023

(54) ETCHANT COMPOSITION OF TITANIUM LAYER AND ETCHING METHOD USING THE SAME

(71) Applicant: ENF TECHNOLOGY CO., LTD., Yongin-si (KR)

(72) Inventors: Sang Seung PARK, Yongin-si (KR); Yang Ryoung KIM, Yongin-si (KR); Bo Yeon LEE, Yongin-si (KR); Min Gyeong JEONG, Yongin-si (KR); Se Hoon KIM, Yongin-si (KR)

(21) Appl. No.: 18/157,006

(22) Filed: Jan. 19, 2023

(30) Foreign Application Priority Data
Jan. 21, 2022 (KR) 10-2022-0009132
Dec. 29, 2022 (KR) 10-2022-0188310

(51) Int. Cl. C09K 13/06; C09K 13/02; H01L 21/3213

(52) U.S. Cl. CPC C09K 13/06; C09K 13/02; H01L 21/32133

(57) ABSTRACT

Provided are an etchant composition of a titanium layer and a method using the same, which may selectively etch the titanium layer without affecting the quality of other layers during a process of manufacturing a semiconductor and a display device, and thus, may increase productivity and reliability with improved etching characteristics in a semiconductor manufacturing process.

### CROSS-REFERENCE TO RELATED APPLICATIONS

This application claims priority under 35 U.S.C. §119 to Korean Patent Application No. 10-2022-0009132, filed on Jan. 21, 2022, and Korean Patent Application No. 10-2022-0188310, filed on Dec. 29, 2022, in the Korean Intellectual Property Office, the disclosure of which is incorporated herein by reference in its entirety.

### TECHNICAL FIELD

The following disclosure relates to an etchant composition of a titanium layer and an etching method using the same, and more particularly, to an etchant composition which may selectively etch a titanium layer without affecting the quality of other layers in a process of manufacturing semiconductor and display devices, and an etching method using the same.

### BACKGROUND

Development of IT technology accelerates high performance and miniaturization of mobile devices such as mobile phones, digital cameras, MP3, and USB memory. Furthermore, smart phones which are currently emerging continue to be developed, aiming for a PC in hand. These products are required to have abilities equivalent to conventional personal computers (PC), and in order to realize the ability, technology development for a semiconductor device satisfying an ultrahigh speed, a large capacity, low power consumption, excellent performance, reliability, and the like is being demanded.

A general semiconductor device is manufactured using one transistor and one capacitor as a unit cell, and the transistor of the semiconductor device generally has a MOS structure. A transistor having the MOS structure includes source electrode, gate electrode, and drain electrode structures, and source electrode and drain electrode terminals are made on a silicon substrate and current flows through the terminal. The gate electrode terminal is designed to apply voltage, and Al is mainly used as a metal on an uppermost part and a silicon oxide is usually used as an oxide layer under the metal layer. Here, for smooth current flow between electrodes, the source electrode, the gate electrode, and the drain electrode described above are connected usually using a titanium silicide (TiSi) layer as wiring.

The titanium silicide layer described above is formed by forming a titanium layer on a substrate on which the source electrode, the gate electrode, and the drain electrode are formed and annealing the formed titanium layer. Here, since the substrate is exposed to the atmosphere during the annealing process, the titanium layer may react with oxygen or water vapor to form a titanium oxide layer. The titanium oxide layer formed as such may cause a problem in forming a titanium silicide layer due to a strong bonding force, which may result in a short phenomenon. In addition, as a semiconductor process is complicated and miniaturized, a problem of reliability degradation due to the defects becomes serious.

Therefore, in order to prevent the defects of a titanium silicide layer, a process of etching a titanium layer is essential after a process of forming a titanium silicide layer. As a conventional technology, Patent Document 1 discloses an etchant composition formed of a fluoric acid, a periodic acid, and a sulfuric acid, and Patent Document 2 discloses an etchant composition formed of hydrogen peroxide, a fluorine-containing compound, a compound containing both an amino group and a carboxyl group, a nitrate compound, a cyclic amine compound, and water. However, the conventional technologies intend to make etching of a titanium layer efficiently using fluorine, but the effect is not sufficient, and also have problems such as metals other than titanium being simultaneously etched and causing damage to the quality of other layers. Besides, an etchant composition using a buffer or a highly concentrated hydrogen peroxide was suggested as a composition for selectively etching a titanium layer, but the damaged quality of other layers and over-etching of a titanium layer still remains as problems.

### Related Art Documents

### Patent Documents

Korean Patent Laid-Open Publication KR 10-2000-0028870 A
Korean Patent Laid-Open Publication KR 10-2011-0019604 A

### SUMMARY

An embodiment of the present invention is directed to providing an etchant composition of a titanium layer having a corrosion prevention effect for the quality of other layers laminated therewith while etching a titanium layer with a rapid etching rate.

Another embodiment of the present invention is directed to providing an etchant composition which does not cause an over-etching problem of a titanium layer and residues, and thus, may stably etch the titanium layer.

Still another embodiment of the present invention is directed to providing an etching method of a titanium layer with improved productivity and reliability, as excellent etching characteristics for a titanium layer and a corrosion prevention effect for the quality of other layers, and a manufacturing method of a semiconductor device.

In one general aspect, an etchant composition includes: an etidronic acid or a salt thereof, an inorganic base, hydrogen peroxide, and a remaining amount of water.

In an exemplary embodiment of the present disclosure, the etidronic acid or the salt thereof may be included at 0.01 to 5 wt% with respect to the total weight of the composition.

In an exemplary embodiment of the present disclosure, the inorganic base may be included at 0.1 to 2.8 wt% with respect to the total weight of the composition.

In an exemplary embodiment of the present disclosure, the inorganic base may be a hydrate.

In an exemplary embodiment of the present disclosure, the etidronic acid or the salt thereof and the inorganic base may be included at a weight ratio of 1:1 to 1:2.5.

The etchant composition according to an exemplary embodiment of the present disclosure may include 0.01 to 5 wt% of the etidronic acid; 0.1 to 2.8 wt% of the inorganic base; 15 to 25 wt% of the hydrogen peroxide; and a remaining amount of water, based on the total weight of the composition.

The etchant composition according to an exemplary embodiment of the present disclosure may not include a quaternary ammonium salt.

The etchant composition according to an exemplary embodiment of the present disclosure may further include a phosphate.

In an exemplary embodiment of the present disclosure, the etchant composition may include 0.01 to 5 wt% of the etidronic acid or the salt thereof, 0.1 to 2.8 wt% of the inorganic base, 15 to 25 wt% of the hydrogen peroxide, 0.01 to 1 wt% of the phosphate, and a remaining amount of water, based on the total weight of the etchant composition.

The etchant composition according to an exemplary embodiment of the present disclosure may further include a chelating agent.

The etchant composition according to an exemplary embodiment of the present disclosure may have a pH of 10 to 12.

The etchant composition according to an exemplary embodiment of the present disclosure may be for etching a titanium-containing metal layer.

In another general aspect, an etching method of a titanium layer includes: bringing a titanium layer into contact with the etchant composition described above.

In still another general aspect, a manufacturing method of semiconductor device includes: forming a titanium layer on a substrate on which a source electrode, a gate electrode, and a drain electrode have been formed; and etching the titanium layer with the etchant composition described above.

In the manufacturing method of a semiconductor device according to an exemplary embodiment of the present disclosure, after the forming of a titanium layer, forming a silicon insulation layer and a single layer of one or a multilayer layer of two or more selected from metal layers are formed on a part of the titanium layer may be further included.

In an exemplary embodiment of the present disclosure, the metal layer may be a single layer or a multilayer layer including one or more metals selected from copper, aluminum, and molybdenum.

The manufacturing method of a semiconductor device according to an exemplary embodiment of the present disclosure may further include annealing the titanium layer, after the etching.

Other features and aspects will be apparent from the following detailed description, the drawings, and the claims.

### BRIEF DESCRIPTION OF THE DRAWINGS

FIG. 1 is a scanning electron microscopic (SEM) image of a substrate (titanium layer/copper layer) etched by an etchant composition of Comparative Example 1 according to the present disclosure.

FIG. 2 is a scanning electron microscopic (SEM) image of a substrate (titanium layer/copper layer) etched by an etchant composition of Example 1 according to the present disclosure.

### DETAILED DESCRIPTION OF EMBODIMENTS

Hereinafter, an etchant composition which selectively etches a titanium layer without affecting other metal layers during a manufacturing process of semiconductor and display devices, an etching method of a titanium layer using the same, and a manufacturing method of a semiconductor device will be described.

Technical terms and scientific terms used herein have the general meaning understood by those skilled in the art to which the present invention pertains unless otherwise defined, and a description for the known function and configuration which may unnecessarily obscure the gist of the present disclosure will be omitted in the following description and the accompanying drawings.

The singular form used in the present specification may be intended to also include a plural form, unless otherwise indicated in the context.

In addition, units used in the present specification without particular mention are based on weights, and as an example, a unit of % or ratio refers to a wt% or a weight ratio and wt% refers to wt% of any one component in a total composition, unless otherwise defined.

In addition, the numerical range used in the present specification includes all values within the range including the lower limit and the upper limit, increments logically derived in a form and span in a defined range, all double limited values, and all possible combinations of the upper limit and the lower limit in the numerical range defined in different forms. Unless otherwise defined in the specification of the present disclosure, values which may be outside a numerical range due to experimental error or rounding of a value are also included in the defined numerical range.

The term “damage of upper layer or lower layer” in the present specification refers to damage caused by etching an upper layer or a lower layer such as a silicon wafer, a silicon insulation layer, and a metal layer in an etching process, for example, occurrence of tip.

The metal layer in the present specification refers to a metal layer which is not to be etched, unless otherwise specifically limited, and specifically, may not contain titanium. In addition, for a clear distinction, it may be named as a second metal layer.

In addition, the term “comprise” in the present specification is an open-ended description having a meaning equivalent to the term such as “is/are provided”, “contain”, “have”, or “is/are characterized”, and does not exclude devices, materials or processes which are not further listed.

In addition, the term “substantially not include” in the present specification means that other devices, materials, or processes which are not listed together with specified devices, materials, or processes may be present in an amount or a degree which does not have an unacceptable significant influence on at least one basic and novel technical idea of the invention.

Hereinafter, the present disclosure will be described in detail.

The etchant composition according to an exemplary embodiment of the present disclosure may include an etidronic acid or a salt thereof, an inorganic base, hydrogen peroxide, and a remaining amount of water. Here, the etchant may refer to an etchant for etching a titanium-containing metal layer.

Hereinafter, the etidronic acid in the present specification may refer to an etidronic acid and/or an etidronic acid salt. Specifically, the etidronic acid salt may be an alkali metal salt, an alkaline earth metal salt, or an ammonium salt of the etidronic acid. A specific example of the alkali metal salt or the alkaline earth metal salt may be a sodium salt, a potassium salt, a calcium salt, or a magnesium salt. In an exemplary embodiment of the present disclosure, the etidronic acid may include an etidronic acid tetrasodium salt, or an etidronic acid tetrapotassium salt.

In the etchant composition according to an exemplary embodiment of the present disclosure, the etidronic acid may be included at 0.01 to 5 wt% with respect to the total weight of the composition. Specifically, it may be included at 0.05 to 3 wt%, 0.05 to 2.5 wt%, or 0.7 to 2 wt%. Here, by including the etidronic acid in the content range, effects of improved etching rate of a titanium layer and improved etching residue washing performance may be provided.

In the etchant composition according to an exemplary embodiment of the present disclosure, the inorganic base may serve as a pH adjusting agent, and a non-limiting example thereof may be selected from sodium hydroxide, potassium hydroxide, sodium carbonate, and the like, and specifically, may be a hydrate.

The inorganic base may be included at 0.1 to 2.8 wt%, 0.5 to 2.8 wt%, 1.0 to 2.8 wt%, or 1.5 to 2.7 wt%, with respect to the total weight of the etchant composition. By including the inorganic base in the range described above, occurrence of titanium residues is prevented, and an effect of suppressing etching of other metals is excellent.

The amount of use may be adjusted depending on the pH, but when the inorganic base is added at 3 wt% or more with respect to the total weight of the composition, an etching rate and a surface uniformity may be decreased, and thus, the amount may not be appropriate.

Besides, according to a preferred exemplary embodiment of the present disclosure, the etidronic acid may be included at 0.1 to 50 parts by weight, specifically 0.5 to 40 parts by weight, and more specifically 0.55 to 35 parts by weight, with respect to 100 parts by weight of the inorganic base. In this case, excellent etching characteristics for a titanium layer are implemented without titanium residues, and other metal layers are not etched, thereby expressing high selectivity. In addition, it is more preferred since titanium ions present in a chemical after an etching process may be stably chelated.

In addition, in this case, since stable etching characteristics are implemented, a change in pH of a chemical may be small even during a repeated etching process. Specifically, the pH of the etchant composition of a titanium layer according to an exemplary embodiment of the present disclosure may be 8 to 13 or 10 to 12. In particular, according to the present disclosure, bubble occurrence by decomposition of hydrogen peroxide due to high pH may be effectively suppressed, and better performance may be shown in suppression of readsorption of etching residues.

The etchant composition according to an exemplary embodiment of the present disclosure may satisfy both a weight ratio between the etidronic acid described above and the inorganic base and a content range of remaining components. Specifically, the etchant composition may include 0.01 to 5 wt% of the etidronic acid, 0.1 to 2.8 wt% of the inorganic base, 15 to 25 wt% of hydrogen peroxide, and a remaining amount of water, based on the total weight.

More specifically, the etchant composition according to the present disclosure may include 0.01 to 3 wt% of the etidronic acid, 1.3 to 2.7 wt% of the inorganic base, 15 to 23 wt% of hydrogen peroxide, and a remaining amount of water.

The etchant composition according to an exemplary embodiment of the present disclosure may further include a phosphate. Specifically, the etchant composition may include 0.01 to 1 wt% or 0.05 to 0.5 wt% of the phosphate, based on a total composition. The phosphate may include monosodium phosphate (NaH₂PO₄), disodium phosphate (Na₂HPO₄), trisodium phosphate (Na₃PO₄), monopotassium phosphate (KH₂PO₄), dipotassium phosphate (K₂HPO₄), monoammonium phosphate ((NH₄)H₂PO₄), diammonium phosphate ((NH₄)₂HPO₄), triammonium phosphate ((NH₄)₃PO₄), or a combination of two or more thereof. Preferably, the phosphate may be monopotassium phosphate (KH₂PO₄), dipotassium phosphate (K₂HPO₄), or a combination thereof. In this case, an etching rate may be adjusted so that uniform etching may proceed.

The etchant composition according to an exemplary embodiment of the present disclosure may satisfy both a weight ratio between the etidronic acid described above and the inorganic base and a content range of remaining components. Specifically, the etchant composition may include 0.01 to 5 wt% of the etidronic acid, 0.1 to 2.8 wt% of the inorganic base, 15 to 25 wt% of hydrogen peroxide, 0.01 to 1 wt% of a phosphate, and a remaining amount of water, based on the total weight.

As a non-limiting exemplary embodiment, the etchant composition according to the present disclosure may further include a chelating agent. The chelating agent may be specifically one or more selected from iminodiacetic acid, nitrilotriacetic acid, ethylenediaminetetraacetic acid, diethylenetrinitrilepenta acetic acid, aminotris(methylenephosphonic acid), (1-hydroxyethane-1,1-diyl)bis(phosphonic acid), ethylenediamine tetra(methylenephosphonic acid), diethylenetriamine penta(methylenephosphonic acid), alanine, glutamic acid, aminobutyric acid, and glycine, and the like, but is not limited thereto. A chelating agent including two or more acid groups, preferably two or three acetic acid groups may be iminodiacetic acid or nitrilotriacetic acid. The chelating agent may be included at 0.01 to 0.2 wt% or 0.05 to 0.1 wt%, based on the total weight of the total composition.

Water included in the etchant composition is not particularly limited, but may be specifically deionized water, and more specifically deionized water for a semiconductor process, having a resistivity value of 18 MΩ.cm or more.

In the etchant composition according to an exemplary embodiment of the present disclosure, a quaternary ammonium salt may not substantially be included. When the etchant composition includes the quaternary ammonium salt, an etching rate for a titanium layer is rapidly improved and causes over-etching, which is thus not preferred. For example, the quaternary ammonium salt may be tetraalkylammonium hydroxide, trialkylarylammonium hydroxide, and the like, and specifically, may be tetramethylammonium hydroxide, tetraethylammonium hydroxide, tetrapropylammonium hydroxide, tetrabutylammonium hydroxide, tetrahexylammonium hydroxide, tetraoactylammonium hydroxide, benzyltriethylammonium hydroxide, diethyldimethylammonium hydroxide, or methyltributylammonium hydroxide, but is not limited as long as it has the embodiment of the quaternary ammonium salt. Here, the alkyl may be C1-C8 alkyl and the aryl may be C6-C12 aryl.

In the etchant composition according to an exemplary embodiment of the present disclosure, an object to be etched of the etchant composition may be a pure titanium layer. According to the present disclosure, etching or damage of the upper layer or the lower layer represented by a silicon insulation layer, a copper-based metal layer, or the like other than the titanium layer does not occur. Therefore, poor electrical device characteristics, for example, short circuit, poor wiring, reduced luminance, and the like, which may occur during a subsequent process may be effectively prevented.

The silicon insulation layer may be one or a combination of two or more selected from a silicon nitride layer, a silicon oxide layer, and the like.

As an example, the silicon nitride may be a SiNₓ layer, a SiON layer, a doped SiNₓ layer (doped SiN layer), or the like.

As an example, the silicon oxide may be a spin on dielectric (SOD) layer, a high density plasma (HDP) layer, a thermal oxide layer, a borophosphate silicate glass (BPSG) layer, a phospho silicate glass (PSG) layer, a boro silicate glass (BSG) layer, a polysilazane (PSZ) layer, a fluorinated silicate glass (FSG) layer, a low pressure tetraethyl orthosilicate (LP-TEOS) layer, a plasma enhanced tetraethyl ortho silicate (PETEOS) layer, a high temperature oxide (HTO) layer, a medium temperature oxide (MTO) layer, an undoped silicate glass (USG) layer, a spin on glass (SOG) layer, an advanced planarization layer (APL) layer, an atomic layer deposition (ALD) layer, a plasma-enhanced (PE) oxide layer, O₃-tetraethyl ortho silicate (O₃-TEOS), or the like.

The copper-based metal layer may be a single layer formed of copper or a copper alloy; or a multilayer layer in which two or more of the single layer are laminated.

As an example, the copper alloy is not limited as long as it is a metal used in an electrode of a semiconductor device, and a non-limiting example thereof may be one or two or more selected from molybdenum, tungsten, titanium, tantalum, chromium, neodymium, niobium, nickel, indium, tin, and the like.

In addition, the present disclosure will describe a use of the etchant composition of a titanium layer described above.

An exemplary embodiment of the present disclosure may be an etching method of a titanium layer including: bringing a titanium layer into contact with the etchant composition.

In addition, an exemplary embodiment of the present disclosure may be a manufacturing method of a semiconductor device including: forming a titanium layer on a substrate on which a source electrode, a gate electrode, and a drain electrode have been formed; and etching the titanium layer using the etchant composition described above.

According to the present disclosure, in selectively etching a titanium layer used as a metal layer for preventing diffusion of a semiconductor device, etching both an upper layer and a lower layer, for example, a silicon wafer, a silicon insulation layer, and a copper-based metal layer is effectively prevented, and only the titanium layer may be selectively etched. In addition, since readsorption of titanium ions which may occur during an etching process is prevented and stable dissolution in a chemical is allowed, titanium residues which may occur therefrom may be efficiently removed, and thus, damage of the upper layer or the lower layer may be minimized. Thus, according to the present disclosure, electrical or physical defects which may occur in an etching process are minimized, thereby implementing stable device characteristics. In addition, it is commercially very advantageous.

The manufacturing method of a semiconductor device according to an exemplary embodiment of the present disclosure may further include forming a silicon insulation layer and a single layer of one or a multilayer layer of two or more selected from metal layers on a part of a surface of the titanium layer, after the forming of a titanium layer.

The metal layer may be a copper-based metal layer, and the copper-based metal layer may be a single layer formed of copper or a copper alloy or a multilayer layer in which two or more of the single layer are laminated, and the copper alloy may include one or two or more selected from molybdenum, tungsten, titanium, tantalum, chromium, neodymium, niobium, nickel, indium, tin, and the like, in addition to copper.

The manufacturing method of a semiconductor device according to an exemplary embodiment of the present disclosure may further include annealing the titanium layer, after the etching. A titanium silicide layer may be formed by the step, and cracks which may occur in the annealing may not be caused by performing the etching step according to the present disclosure. That is, according to the present disclosure, a titanium silicide layer having improved performance may be provided.

Hereinafter, the etchant composition of a titanium layer according to the present disclosure will be described in more detail by the following examples. However, the following examples are only a reference for describing the present disclosure in detail, and the present disclosure is not limited thereto and may be implemented in various forms.

### Examples 1 to 7, and Comparative Examples 1 to 12

Etchant compositions (8 kg) having the components and the contents listed in Table 1 were prepared.

TABLE 1

| unit: wt% | H₂O₂ | Etidronic acid | | Phosphate-based compound | | Polyvalent phosphonicacid-based or Chelating agent | | Inorganic base | Water | |
|---|---|---|---|---|---|---|---|---|---|---|
| Example 1 | 20 | HEDP | 0.01 | - | - | - | - | KOH | 1.50 | Remaining amount |
| Example 2 | 20 | HEDP | 0.10 | - | - | - | - | KOH | 1.80 | Remaining amount |
| Example 3 | 20 | HEDP | 1.00 | - | - | - | - | KOH | 2.20 | Remaining amount |
| Example 4 | 20 | HEDP-4K | 0.50 | K₂HPO₄ | 0.1 | - | - | KOH | 2.70 | Remaining amount |
| Example 5 | 22 | HEDP-4Na | 0.50 | K₂HPO₄ | 0.1 | - | - | KOH | 2.30 | Remaining amount |
| Example 6 | 18 | HEDP | 0.70 | K₂HPO₄ | 0.1 | - | - | KOH | 2.10 | Remaining amount |
| Example 7 | 20 | HEDP | 0.20 | K₂HPO₄ | 0.1 | IDA | 0.08 | NaOH | 2.20 | Remaining amount |
| Example 8 | 20 | HEDP | 0.01 | K₂HPO₄ | 0.1 | - | - | KOH | 1.50 | Remaining amount |
| Comparative Example 1 | 20 | - | - | K₂HPO₄ | 0.1 | NMTP | 1.5 | KOH | 1.90 | Remaining amount |
| Comparative Example 2 | 20 | - | - | K₂HPO₄ | 0.1 | MDPA | 1.5 | KOH | 2.40 | Remaining amount |
| Comparative Example 3 | 20 | - | - | K₂HPO₄ | 0.1 | EDPA | 1.5 | KOH | 2.30 | Remaining amount |
| Comparative Example 4 | 20 | - | - | K₂HPO₄ | 0.1 | CA | 1.5 | KOH | 1.50 | Remaining amount |
| Comparative Example 5 | 20 | - | - | K₂HPO₄ | 0.1 | IDS | 1.5 | KOH | 1.50 | Remaining amount |
| Comparative Example 6 | 20 | HEDP | 1.00 | - | - | - | - | CHA | 3.00 | Remaining amount |
| Comparative Example 7 | 20 | HEDP | 1.00 | - | - | - | - | HxA | 3.00 | Remaining amount |
| Comparative Example 8 | 20 | HEDP | 1.00 | - | - | - | - | DEA | 3.00 | Remaining amount |
| Comparative Example 9 | 20 | HEDP | 1.00 | - | - | - | - | TEA | 3.00 | Remaining amount |
| Comparative Example 10 | 20 | HEDP | 0.30 | - | - | - | - | KOH | 3.00 | Remaining amount |
| Comparative Example 11 | 20 | HEDP | 0.70 | - | - | - | - | KOH | 3.00 | Remaining amount |
| Comparative Example 12 | 20 | HEDP | 1.00 | - | - | - | - | KOH | 3.00 | Remaining amount |

HEDP: 1-hydroxyethylidene-1,1-diphosphonic acid, Etidronic acid
NMTP: [nitrilotris(methylene)]tris(phosphonic acid)
MDPA: methylene diphosphonic acid
EDPA: ethylene diphosphonic acid
CA: citric acid
K2HPO4: dipotassium phosphate
IDA: iminodiacetic acid
IDS: iminodisuccinic acid
KOH: potassium hydroxide
NaOH: sodium hydroxide
CHA: cyclohexylamine
HxA: hexylamine
DEA: diethyleneamine
TEA: triethyleneamine

### Evaluation Method

### 1. Etching Characteristics

A substrate in which a titanium layer (600 Å), a silicon oxide layer (600 Å), and a copper layer (600 Å) were deposited, respectively, as a single layer on a silicon wafer (600 Å) was prepared. A glass in which a pattern was formed by applying a photoresist process having a certain pattern thereon was cut into 5×5 cm using a diamond knife to prepare a specimen.

Etchant compositions obtained from the examples and the comparative examples were prepared to be 8 kg. Each etchant composition prepared was placed in spray etching type experimental equipment, the temperature was set to 32° C., and etching was performed when the temperature was reached. A total etching time was based on an end point detection (EPD) to perform an over-etching of 100%. Thereafter, washing with distilled water three times, each change in a layer thickness was confirmed by Ellipsometer (SE-MG-1000), and etching characteristics were evaluated.

### 2. Titanium Residue Level

The specimen obtained by the etching characteristics evaluation method was used to evaluate a titanium residue level, by the following criteria.

[Criterion 1] Titanium residue level
No residue: ◯
1 to 10 residues: Δ
More than 10 residues/bundle: ×

### 3. Whether Metal Layer (Copper Layer) Was Etched

The specimen obtained by the etching characteristics evaluation method was used to determine whether other metal layers (copper layer) were etched by the following criteria.

[Criterion 2] Etching rate of other metal layers (copper layer)
No etching: ◯
In a range of 1 Å/min to 20 Å/min: Δ
More than 20 Å/min: ×

TABLE 2

| | Ti (ppm) | Etching characteristics (100% OE ≤ 0.3 µm) | Titanium residue level | Whether other metal layers were etched |
|---|---|---|---|---|
| Example 1 | 0 | 0.28 | ◯ | ◯ |
| | 300 | 0.29 | | |
| | 600 | 0.29 | | |
| Example 2 | 0 | 0.27 | ◯ | ◯ |
| | 300 | 0.27 | | |
| | 600 | 0.27 | | |
| Example 3 | 0 | 0.26 | ◯ | ◯ |
| | 300 | 0.27 | | |
| | 600 | 0.26 | | |
| Example 4 | 0 | 0.26 | ◯ | ◯ |
| | 300 | 0.27 | | |
| | 600 | 0.27 | | |
| Example 5 | 0 | 0.25 | ◯ | ◯ |
| | 300 | 0.26 | | |
| | 600 | 0.26 | | |
| Example 6 | 0 | 0.28 | ◯ | ◯ |
| | 300 | 0.28 | | |
| | 600 | 0.29 | | |
| Example 7 | 0 | 0.27 | ◯ | ◯ |
| | 300 | 0.28 | | |
| | 600 | 0.28 | | |
| Example 8 | 0 | 0.27 | ◯ | ◯ |
| | 300 | 0.28 | | |
| | 600 | 0.29 | | |

(TABLE 3)

| | Ti (ppm) | Etching characteristics (occurrence of over-etching) | Titanium residue level | Whether other metal layers were etched |
|---|---|---|---|---|
| Comparative Example 1 | 0 | 0.38 | ◯ | Δ |
| | 300 | 0.35 | | |
| | 600 | 0.34 | | |
| Comparative Example 2 | 0 | 0.36 | ◯ | Δ |
| | 300 | 0.31 | | |
| | 600 | 0.24 | | |
| Comparative Example 3 | 0 | 0.35 | ◯ | Δ |
| | 300 | 0.33 | | |
| | 600 | 0.26 | | |
| Comparative Example 4 | 0 | 0.40 | ◯ | X |
| | 300 | 0.38 | | |
| | 600 | 0.32 | | |
| Comparative Example 5 | 0 | 0.42 | ◯ | X |
| | 300 | 0.41 | | |
| | 600 | 0.41 | | |
| Comparative Example 6 | 0 | 0.32 | Δ | Δ |
| | 300 | 0.38 | | |
| | 600 | 0.22 | | |
| Comparative Example 7 | 0 | 0.31 | X | Δ |
| | 300 | 0.26 | | |
| | 600 | 0.19 | | |
| Comparative Example 8 | 0 | 0.36 | X | Δ |
| | 300 | 0.32 | | |
| | 600 | 0.31 | | |
| Comparative Example 9 | 0 | 0.33 | X | X |
| | 300 | 0.28 | | |
| | 600 | 0.20 | | |
| Comparative Example 10 | 0 | 0.32 | ◯ | Δ |
| | 300 | 0.28 | | |
| | 600 | 0.20 | | |
| Comparative Example 11 | 0 | 0.34 | ◯ | X |
| | 300 | 0.26 | | |
| | 600 | 0.18 | | |
| Comparative Example 12 | 0 | 0.36 | Δ | X |
| | 300 | 0.33 | | |
| | 600 | 0.31 | | |

As shown in Table 2 and FIG. 2, it was confirmed that the etchant composition according to the present disclosure showed excellent etching characteristics for a titanium layer. Specifically, in all of the examples, over-etching of a titanium layer was not caused even with an over-etching of 100%, and the titanium residues were not confirmed. Furthermore, it was confirmed that a protection effect for other metal layers was excellent in that etching of a copper layer did not occur in all of the examples,

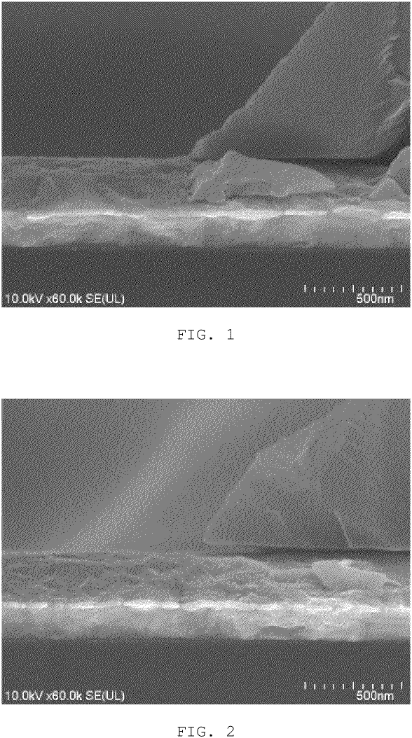

However, as shown in Table 3 and FIG. 1, when an over-etching of 100% proceeded with the etchant compositions of the comparative examples, over-etching was caused. In addition, since a plurality of titanium residues remained, and not only a titanium layer but also a copper layer deposited therewith was etched, it was confirmed that the etchant compositions were inappropriate for protecting other metal layers such as a copper layer.

According to the present disclosure, not only a titanium layer may be selectively rapidly etched, but also a corrosion prevention effect for a silicon insulation layer or a metal layer including a copper-based metal layer or the like may be implemented. In particular, not only a concentration of hydrogen peroxide may be lowered and etching characteristics may be maintained by an optimized content combination of an etidronic acid and a predetermined inorganic base, but also over-etching of a titanium layer may be prevented.

According to the present disclosure, a pH change in a chemical is small with the implement of stable etching characteristics, and a bubble generation problem due to the decomposition of hydrogen peroxide by high pH may be solved. In addition, since a quaternary ammonium salt which may cause over-etching of a titanium layer or residues by a reaction with hydrogen peroxide may not be included, a titanium layer may be more stably etched.

According to the present disclosure, damage of an upper layer and a lower layer such as a silicon wafer, a silicon insulation layer, and a copper-based metal layer is minimized, thereby stably performing a subsequent process. In particular, according to the present disclosure, a precisely controlled titanium layer may be provided without damage of the upper layer and the lower layer described above. Thus, poor electrical device characteristics, for example, short circuit, poor wiring, reduced luminance, and the like, which may occur during a subsequent process, may be prevented. Thus, the etchant composition according to the present disclosure may be useful for an etching process through selective etching of a titanium layer and a manufacturing method of a semiconductor device including the etching process.

Hereinabove, although the present disclosure has been described by specific matters and the limited examples and comparative examples, they have been provided only for assisting the entire understanding of the present disclosure, and the present disclosure is not limited to the exemplary embodiments, and various modifications and changes may be made by those skilled in the art to which the present disclosure pertains from the description. Therefore, the spirit of the present disclosure should not be limited to the above-described exemplary embodiments, and the following claims as well as all modified equally or equivalently to the claims are intended to fall within the scope and spirit of the disclosure.

What is claimed is:

1. An etchant composition comprising: an etidronic acid or a salt thereof, an inorganic base, hydrogen peroxide, and a remaining amount of water.

2. The etchant composition of claim 1, wherein the etidronic acid or the salt thereof is included at 0.01 to 5 wt% with respect to a total weight of the composition.

3. The etchant composition of claim 1, wherein the inorganic base is included at 0.1 to 2.8 wt% with respect to the total weight of the composition.

4. The etchant composition of claim 1, wherein the inorganic base is a hydrate.

5. The etchant composition of claim 1, wherein the etidronic acid or the salt thereof and the inorganic base are included at a weight ratio of 1: 1 to 1:2.5.

6. The etchant composition of claim 1, wherein 0.01 to 5 wt% of the etidronic acid or the salt thereof; 0.1 to 2.8 wt% of the inorganic base; 15 to 25 wt% of the hydrogen peroxide; and a remaining amount of water are included, based on the total weight of the etchant composition.

7. The etchant composition of claim 1, wherein a quaternary ammonium salt is not included.

8. The etchant composition of claim 1, further comprising a phosphate.

9. The etchant composition of claim 8, wherein 0.01 to 5 wt% of the etidronic acid or the salt thereof; 0.1 to 2.8 wt% of the inorganic base; 15 to 25 wt% of the hydrogen peroxide; 0.01 to 1 wt% of the phosphate; and a remaining amount of water are included, based on the total weight of the etchant composition.

10. The etchant composition of claim 1, further comprising a chelating agent.

11. The etchant composition of claim 1, wherein a pH is 10 to 12.

12. The etchant composition of claim 1, wherein the etchant is for etching a titanium-containing metal layer.

13. An etching method of a titanium layer comprising: bringing a titanium layer into contact with the etchant composition of claim 1.

14. A manufacturing method of a semiconductor device, the method comprising:
forming a titanium layer on a substrate in which a source electrode, a gate electrode, and a drain electrode have been formed; and
etching the titanium layer with the etchant composition of claim 1.

15. The manufacturing method of a semiconductor device of claim 14, further comprising: forming a silicon insulation layer and a single layer of one or a multilayer layer of two or more selected from metal layers on a part of a surface of the titanium layer, after the forming of a titanium layer.

16. The manufacturing method of a semiconductor device of claim 15, wherein the metal layer is a single layer or a multilayer layer including one or more metals selected from copper, aluminum, and molybdenum.

17. The manufacturing method of a semiconductor device of claim 14, further comprising: annealing the titanium layer, after the etching.
